(19) United States
(12) Patent Application Publication
(10) Pub. No.: US 2023/0354693 A1
(43) Pub. Date: Nov. 2, 2023

(54) SUPERFLUORESCENT CERIUM (III)-CONTAINING CHELATE APPLICABLE TO PHOTOELECTRIC DEVICES AND HAVING A DUAL CAPTURE MECHANISM AND ULTRA-SHORT DECAY TIME

(71) Applicant: SICHUAN KNOWLEDGE EXPRESS INSTITUTE FOR INNOVATIVE TECHNOLOGIES CO., LTD, Meishan, Sichuan (CN)

(72) Inventor: Hartmut YERSIN, Sinzing (DE)

(73) Assignee: SICHUAN KNOWLEDGE EXPRESS INSTITUTE FOR INNOVATIVE TECHNOLOGIES CO., LTD, Meishan, Sichuan (CN)

(21) Appl. No.: 17/794,947

(22) PCT Filed: Jan. 16, 2021
(86) PCT No.: PCT/CN2021/072344

§ 371 Date: Jul. 23, 2022

(30) Foreign Application Priority Data
Feb. 10, 2020 (DE) 10 2020 103 268.4

(51) Int. Cl. H10K 85/30; C07F 5/00; H10K 85/40; H10K 85/60; C07F 7/08; C09K 11/06

(52) U.S. Cl. CPC H10K 85/351; C07F 5/003; C07F 7/081; C09K 11/06; H10K 85/40; H10K 85/623; H10K 85/636; H10K 85/658; H10K 50/121

(57) ABSTRACT

The present invention relates to a composition of a superfluorescent cerium (III)-containing chelate having ultra-short decay time, especially a molecular composition for OLED applications, having a neutral donor in the form of a Ce(III) chelate and a neutral fluorescent receptor molecule. The composition of the present invention can be used to produce pure color luminescence with very short emission decay time, especially for a dark blue luminous region. The composition utilizes an excited state dual capture mechanism, and such kind of novel exciton capture mechanism can be classified into a fifth-generation organic light-emitting diode (OLED) and other photoelectric devices.

### TECHNICAL FIELD

The present invention relates to a composition for non-radiative energy transfer with a cerium (III) chelate molecule as a donor and a fluorescent molecule as a receptor, thereby producing superfluorescence with a small full width at half maximum and short decay time, in particular to the production of dark blue emission.

After being combined with cerium (III) chelate molecules, blue, green or red luminous fluorescent receptor materials can produce the emission of superfluorescence with a high color purity and short service life within the corresponding spectral range.

### BACKGROUND

OLED has profoundly created or at least affected the screen technology, and even partial lighting technologies. For example, summary related to the prior art can be found in Yersin, H. (Ed.). (2008). Highly efficient OLEDs with phosphorescent materials (phosphorescence-based efficient OLED). John Wiley & Sons. And Yersin, H. (Ed.). (2019). Highly efficient OLEDs: Materials based on thermally activated delayed fluorescence (efficient OLED: materials based on thermally activated delayed fluorescence). John Wiley & Sons.

However, there are still shortcomings, in particular to the aspect of luminous layer materials, especially in blue light-emitting materials. Up to now, the color purity and enough stability demanded by efficient OLED devices have been not satisfied. Moreover, color purity requirements for a green emitter and a red emitter have been not completely satisfied, either.

The method to solve such a problem is to ensure that all the, namely 100% singlet or triplet excitons produced in the OLED light emitting layer are captured by an emitter based on thermally activated delayed fluorescence, namely, the so-called TADF emitter. Yersin, H. (Ed.). (2019). Highly efficient OLEDs: Materials based on thermally activated delayed fluorescence (efficient OLED: materials based on thermally activated delayed fluorescence). John Wiley & Sons., H.Yersin, U. Monkowius, DE 10 2008 033563, registered on Jul. 17, 2008; Uoyama, H., Goushi, K., Shizu, K., Nomura, H., & Adachi, C. (2012). Highly efficient organic light-emitting diodes from delayed fluorescence. Nature, 492(7428), 234-238. However, these materials usually show a wider emission band with a full width at half maximum of 4000 cm⁻¹ (FWHM, 0.5 eV). Therefore, for example, a light-emitting material whose maximum emission peak is located in the dark blue region) also has equivalent intensity in a green light region, thus causing that sky blue instead of dark blue emits light. Therefore, the improvement for color purity is still highly expected.

The method to solve the problem of color purity is to further introduce an additional component, namely, a pure organic fluorescent molecule F besides using a TADF emitter with a larger FWHM in the OLED light emitting layer. The fluorescent spectrum of the molecule has an obviously narrower FWHM (for example, less than 0.25 eV) than that of the TADF emitter. What’s more, the fluorescent molecule F is suitable for effectively eliminating TADF emission (donor) and effective spontaneous production of fluorescence (a receptor) through non-radiative energy transfer of a Foerster energy transfer mechanism (dipole-to-dipole energy transfer) (the Foerster energy transfer mechanism is well known by a person skilled in the art). For example, corresponding conditions have been discussed in references [Turro, N. (1978). Modern Molecular Photochemistry. Menlo Park, California: The Benjamin/Cummings Publishing Co.; Barltrop, J. A., & Coyle, J. D. (1975). Excited states in organic chemistry. Wiley.; Baumann, T., Budzynski, M., & Kasparek, C. (2019, June). 33-3: TADF Emitter Selection for Deep-Blue Hyper-Fluorescent OLEDs. In SID Symposium Digest of Technical Papers (Vol. 50, No. 1, pp. 466-469).] The importance of the mechanism is that the spectrum of the donor emission (TADF emission herein) and receptor absorption (fluorescent molecule F herein) has better overlaps; the fluorescent molecule F has a high decimal molar extinction coefficient Ɛ(Ɛ>25000 Lmol⁻¹cm⁻¹) at the overlapping absorption band. A mean space between the TADF emitter and the fluorescent molecule F is generally not more than 3-4 nm. Moreover, it must be excluded that the mean space between the TADF emitter and the fluorescent molecule F is less than 1 nm. Specific reasons will be discussed hereafter. Thus as can be seen, an OLED emitting dark blue light and having a suitable color purity (CIE y component <0.15) and a good device efficiency (EQE is close to 20%) can be obtained according to the concept. The method is generally called a superfluorescent mechanism. [Adachi, C. (2013, June). 37.1: Invited Paper: Third Generation OLED by Hyperfluorescence. In SID Symposium Digest of Technical Papers (Vol. 44, No. 1, pp. 513-514). Oxford, UK: Blackwell Publishing Ltd.; Nakanotani, H., Higuchi, T., Furukawa, T., Masui, K., Morimoto, K., Numata, M., ... & Adachi, C. (2014). High-efficiency organic light-emitting diodes with fluorescent emitters. Nature communications, 5(1), 1-7.; Han, S. H., & Lee, J. Y. (2018). Spatial separation of sensitizer and fluorescent emitter for high quantum efficiency in hyperfluorescent organic light-emitting diodes. Journal of Materials Chemistry C, 6(6), 1504-1508.; Jang, J. S., Han, S. H., Choi, H. W., Yook, K. S., & Lee, J. Y. (2018). Molecular design of sensitizer to suppress efficiency loss mechanism in hyper-fluorescent organic light-emitting diodes. Organic Electronics, 59, 236-242.; Byeon, S. Y., Lee, D. R., Yook, K. S., & Lee, J. Y. (2019). Recent Progress of Singlet - Exciton - Harvesting Fluorescent Organic Light - Emitting Diodes by Energy Transfer Processes. Advanced Materials, 31(34), 1803714.; Baumann, T., Budzynski, M., & Kasparek, C. (2019, June). 33 - 3:TADF Emitter Selection for Deep - Blue Hyper - Fluorescent OLEDs. In SID Symposium Digest of Technical Papers (Vol. 50, No. 1, pp. 466-469).] However, up to now, only limited service life of device has been achieved by TADF donor molecules and suitable acceptor molecules. [Baumann, T., Budzynski, M., & Kasparek, C. (2019, June). 33 - 3: TADF Emitter Selection for Deep - Blue Hyper - Fluorescent OLEDs. In SID Symposium Digest of Technical Papers (Vol. 50, No. 1, pp. 466-469).]

Stability of the OLED device can be obviously improved by shortening the emission decay time of an emitter. [Noda, H., Nakanotani, H., & Adachi, C. (2018). Excited state engineering for efficient reverse intersystem crossing. Science advances, 4(6), eaao6910.]. The reason is to obviously decrease the chemical reaction or decomposition in the excited state by shortening the emission decay time of an emitter. Moreover, to shorten the emission decay time of an emitter also significantly improves the roll-off behavior of device (decreased device efficiency appears with the increase of electric current density or brightness). Up to now, the known TADF emitters have had relatively longer emission decay time, namely, about a few microseconds. Therefore, there is a demand for obviously shortening the emission decay time of donor molecules over the prior art. This is also the task of this present invention. Certainly, similar to the TADF emitter, all the excitons produced on the light emitting layer must be captured.

### SUMMARY

The above shortcomings may be improved by the present invention.

Surprisingly, the composition of the Ce(III) chelate (donor) and fluorescent receptor molecule F eliminates the shortcoming of long decay time (a few microseconds) of TADF. The reason is that (radioactive) Ce(III) chelate has delay time less than 100 ns, which is shorter than the TADF emitters used up to now by more than 50 times. The composition with the acceptor molecule F produces narrow-band fluorescence, namely, superfluorescence (FIG. 1) after effective non-radiative energy transfer (based on the Foerster mechanism).

### Donor

The neutral Ce donor chelate used in the composition of the fluorescent molecule F in the present invention consists of Ce(III) central ions; the Ce(III) central ions are eight-coordinated, preferably, nine-coordinated or twelve-coordinated at most, and coordinated by an organic chelate ligand.

The ligand of the Ce donor chelate is preferably two-coordinated or particularly preferably three-coordinated chelate ligand. The ligand includes, for example, a small organic aromatic ring or aromatic ring system, for example, preferably a monocyclic ring or bicyclic system; these ring systems are suitable for capturing singlet or triplet excitons. It means that the lowest ligand excited singlet state S₁(L) and the lowest ligand excited triplet state T₁(L) are occupied. The ligand is selected in such way to make the lowest singlet state higher than the emission state of Ce(III) in energy. The belonging energy state may be determined by current spectral measurement methods conveniently. The corresponding energy determination may be also obtained by quantum chemistry (for example, based on a TD-DFT method).

Rapid intersystem crossing and vibration relaxation of S₁(L)→T₁(L) between coordinate states are achieved on the basis of a high spin-orbit coupling constant of Ce (690 cm⁻¹). Similarly, rapid non-radiative energy transfer of the lowest excited state from state T₁(L) to the center of Ce(III) is then performed in molecules. A spinning and parity-allowable ²D_{⅔} (5d*) states are related herein. Valid and rapid 5d→4f emission occurs in the ²F_{5/2} and ²F_{7/2} states having approximate energy therewith (distance ≈ 2000 cm⁻¹), and is accompanied with 50-100 ns decay time (no acceptor molecule is related). (FIG. 1) Such jumping at the center of Ce(III) is a fluorescent radiation process. The related Ce(III) chelate is neither a non-simple TADF singlet capture mechanism nor a non-simple triplet capture mechanism, but a novel exciton capture mechanism related to dual capture, capable of being classified into the capture mechanism of the fifth-generation OLED. The capture mechanism of the fourth-generation OLED is described in (Yersin, H., Mataranga-Popa, L., Czerwieniec, R., & Dovbii, Y. (2019). Design of a New Mechanism beyond Thermally Activated Delayed Fluorescence Toward Fourth Generation Organic Light Emitting Diodes. Chemistry of Materials, 31(16), 6110-6116.)

In a preferred embodiment, the donor chelate is, for example, a molecule of formula I or II.

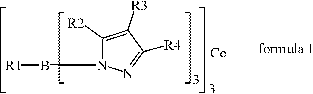

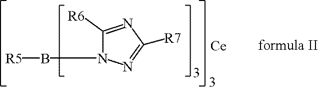

where:
R¹ is selected from pyrazolyl, triazolyl, heteroaryl, alkyl, aryl, alkoxy, phenol group, amido and acylamino; these groups may be substituted or unsubstituted, or particularly a carbazolyl (Cz)- group or a carbazolyl group substituted by one or two tert-butyl.
R⁵=R¹ or H, and
R², R³, R⁴, R⁶, R⁷ are independently selected from H, halogen, or hydrocarbonyl containing a heteroatom, especially alkyl, aryl and heteroaryl. To improve the volatility of compounds, R²-R⁷ may be each independently fluorinated, namely, particularly having at least one F.

In a preferred embodiment, the donor chelate is the following compound: Ce[pz₃B(2,7-t-Bu₂-Cz)]₃, Ce[pz₃B(3,6-t-Bu₂-Cz)]₃ or Ce[pz₃B(4,5-t-Bu₂-Cz)]₃ and a compound carrying carbazolyl a tert-butyl on carbazolyl in any position. Similarly and preferably, one or two carbazolyl groups carry one or two substances substituted by tert-butyl. In an embodiment, a chelate without tert-butyl is preferred, namely, subjected to the following molecular formula Ce[pz₃B(Cz)]₃.

Surprisingly, a luminous device with outstanding properties may be obtained in the light emitting layer on the basis of the chelate of formula I or II used in the present invention. An air-stable and soluble Ce chelate (substance of formula I) may be obtained by a group R1 different from the group H. Meanwhile, it is found that the expected properties are obtained when the pyrazolyl group is substituted by a triazolyl group (a compound of formula II).

In another preferred embodiment, based on the donor chelate used in the composition of the present invention, for example, a substituted compound is configured at B atoms, particularly for such kind of compound synthesized most easily. In such case, the compound has a preferred formula III or IV.

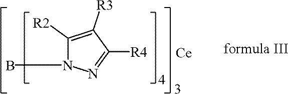

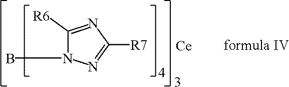

The compound is a tetra(cis)pyrazolyl borate ligand or a tetra(cis)triazolylborate ligand here.

The compound has the following major advantage: these compounds have good solubility and good stability to water and oxygen in H₂O, MeOH, EtOH, MeCN, CHCl₃, CH₂Cl₂ and the like. Therefore, the compound is rather suitable for spin coating, printing and/or ink jet printing process. The compound may be coated by vacuum sublimation or a vapor deposition method. Another major advantage is to simplify the synthesis of Ce chelates, namely, it is not necessary to perform synthesis in a protective atmosphere and anhydrous solvent. The chelate may be also modified by the substitution or change of a ligand. Therefore, there are multiple possibilities to modify or regulate the light emitting properties (for example, transition energy, color, quantum efficiency, decay time and the like).

The Ce center in these donor chelates preferably has at least 9 coordinates, thus preventing decomposition. The substituent R¹ or R⁵ at the B atom is away from the center of the chelate, which will not disturb the coordinate. The solubility may be regulated according to these substituents. When R¹=H, as described in the prior art, a slightly soluble chelate is obtained. For the substituent R¹, based on the present invention, for example, R¹=pyrazolyl, a soluble chelate may be obtained. Therefore, a substance perfectly suitable for wet chemistry processing is obtained, which is an important technological superiority.

R¹ is preferably pyrazolyl; R⁵ may be H; preferably, R⁵ is a residue of not H. Particularly preferably, R⁵ is triazolyl.

The residues R², R³, R⁴, R⁶ and R⁷ (in the formulas III and IV) are each independently selected from hydrogen and halogen, or one hydrocarbonyl optionally containing a heteroatom and/or substituted hydrocarbonyl.

The heteroatom is particularly selected from O, S, N, P, Si, Se, F, Cl, Br and/or I. The residues R¹-R⁷ may include 0-10, or preferably 0-5 heteroatoms. If a residue (for example R⁵) is H, R⁵ has no heteroatom. In some embodiments, the residues R¹-R⁷ may each include at least 1, and particularly have at least 2 heteroatoms. The heteroatom may also exist in the skeleton of a substituent or exists as a portion of a substituent. In one embodiment, the residues R¹-R⁷ are hydrocarbonyl; the hydrocarbonyl has one or more substituents (functional groups). A proper substituent or functional group, for example, is halogen (namely, F, Cl, Br or I), alkyl (particularly C₁-C₂₀, preferably C₁-C₆ alkyl), aryl, O-alkyl, O-aryl, S-aryl, S-alkyl, P-alkyl₂, P-aryl₂, N-alkyl₂ or N-aryl₂. In lots of cases, preferably, at least one of the residues R¹-R⁷ contains at least one F, thus increasing the volatility of chelate.

Hydrocarbonyl is preferably alkyl, alkenyl, alkynyl, aryl or heteroaryl, particularly alkyl, aryl or heteroaryl.

Unless otherwise stated, preferably, the term alkyl (Alkyl-) or alkyl (Alk-) used herein respectively and independently represents C₁-C₂₀, particularly C₁-C₆ hydrocarbonyl. The term aryl represents an aromatic system, for example, an aromatic ring containing 5-12 carbon atoms, where the carbon atom may be substituted by a heteroatom (for example, substituted by N, S or O).

All the substituents R², R³, R⁴, R⁶ and R⁷ are preferably hydrogen or halogen, namely, a substituent without high space requirements. Other examples with small space requirements are, for example, given in formulas I and II.

With regard to the applications of the donor chelate producing dark blue superfluorescence in the present invention, the size of the aromatic or heteraromatic group used in organic ligands is preferably limited to a monocyclic ring or bicyclic ring system.

Other preferred embodiments of the donor molecule are represented in formula V,

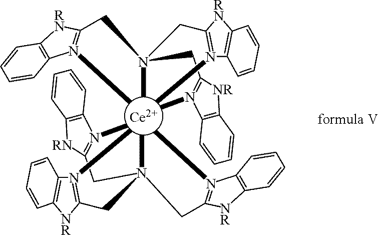

where R is, for example, CH₃CH₂, CH₃CH₂CH₂ or CH₃-CH-CH₃.

Another embodiment of the Ce(III) donor chelate is formula VI.

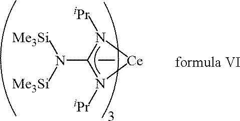

The Ce(III) donor chelate has the maximum emission peak of about 440 nm, a full width at half maximum (FWHM) of about 4000 cm⁻¹ (0.5 eV); and the decay time is determined to be about 50 ns; the photoluminescent quantum efficiency φ_{PL} is between about 60% and 85%. The maximum emission peak of the chelate under the conditions of solution (ethanol) and powder has the approximately identical value. The ligand of the Ce(III) chelate is partially or completely deuterated to achieve the increase of the φ_{PL} value and the corresponding OLED efficiency.

### Receptor

The fluorescent receptor molecule used as a composition together with the Ce(III) donor chelate in the present invention is a pure organic compound; the emission decay time is less than 10 ns or preferably less than 2 ns. The absorption band of the receptor must be within the emission region of the Ce(III) donor chelate, which thus presents an obvious spectral overlap between donor emission and receptor absorption. The purpose is to achieve the effective non-radiative energy transfer based on a Förster mechanism. Furthermore, it is necessary that the receptor has a decimal molar extinction coefficient greater than 20,000 or preferably greater than 40,000 Lmol⁻¹cm⁻¹. In case of blue emission, the Förster energy transfer radius is 3-4 nm. The conditions of the efficient non-radiative energy transfer are known by a person skilled in the art, and can be found by reference to, for example, the following references [Turro, N. J., & Photochemistry, M. M. (1978). Benjamin/Cummings. Menlo Park, CA, 317-319.; Barltrop, J. A., & Coyle, J. D. (1975). Excited states in organic chemistry. Wiley.; aumann, T., Budzynski, M., & Kasparek, C. (2019, June). 33 - 3:TADF Emitter Selection for Deep - Blue Hyper - Fluorescent OLEDs. In SID Symposium Digest of Technical Papers (Vol. 50, No. 1, pp. 466-469).]. Receptor fluorescent molecules used for dark blue superfluorescence should produce such an emission; the maximum emission value is within the scope of about 420-480 nm, or particularly preferably within the scope of about 450-470 nm; and the full width at half maximum (FWHM) is narrower than 0.25 or preferably narrower than 0.2 or 0.18 eV. Moreover, the emission quantum efficiency φ_{PL} (without donor molecule) is higher than 70% or preferably superior to 90%.

Decimal molar extinction coefficient Ɛ may be conveniently determined by a current spectrophotometer.

In one embodiment of dark blue emission, the fluorescent receptor is a molecule TBPe (formula VII):

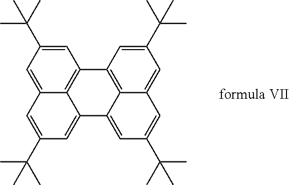 [SMILES: CC(C)(C)c1cc2cc(C(C)(C)C)cc3c4cc(C(C)(C)C)cc5cc(C(C)(C)C)cc(c(c1)c23)c54]

The compound is featured by four tert-butyl groups. These groups are used for expanding the spatial distance between the donor and the receptor, which avoids the short-range energy transfer process with a transfer radius of about 1 nm to the state T₁ of the receptor based on the Deter mechanism to a large extent. This is important because for a normal fluorescent molecule (exclusive of TADF molecule), the occupation of T₁ state will cause exciton loss. The reason is that the T₁ state suffers forbidden transition instead of non-radiative inactivation.

In another embodiment of dark blue receptor emission, BPPyA molecules (formula VIII) with λₘₐₓ=458 nm and φ_{PL}=98% are selected:

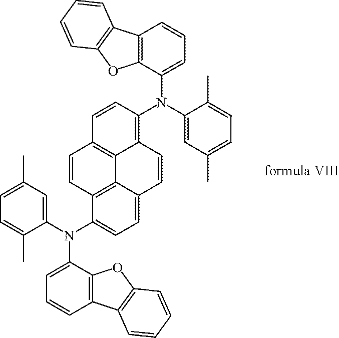 [SMILES: Cc1ccc(C)c(N(c2ccc3ccc4c(N(c5cc(C)ccc5C)c5cccc6c5oc5ccccc56)ccc5ccc2c3c54)c2cccc3c2oc2ccccc23)c1]

In another embodiment of dark blue emission of a fluorescent receptor, compounds having emission data of λₘₐₓ=456 nm, FWHM=0.18 eV and CIE-y=0.09 based on the formula IX are selected.

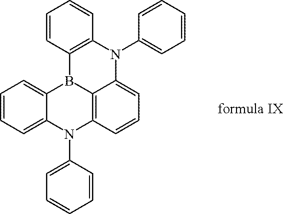 [SMILES: c1ccc(N2c3ccccc3B3c4ccccc4N(c4ccccc4)c4cccc2c43)cc1]

In other embodiments, other fluorescent receptor molecules of device for emitting blue, green and red lights are used. Examples are set forth below.

Other examples of blue emitters (receptor):

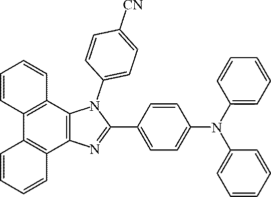 [SMILES: N#Cc1ccc(-n2c(-c3ccc(N(c4ccccc4)c4ccccc4)cc3)nc3c4ccccc4c4ccccc4c32)cc1]

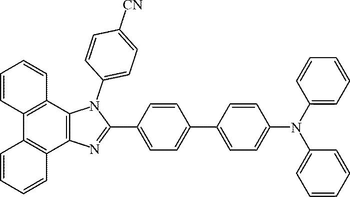 [SMILES: N#Cc1ccc(-n2c(-c3ccc(-c4ccc(N(c5ccccc5)c5ccccc5)cc4)cc3)nc3c4ccccc4c4ccccc4c32)cc1]

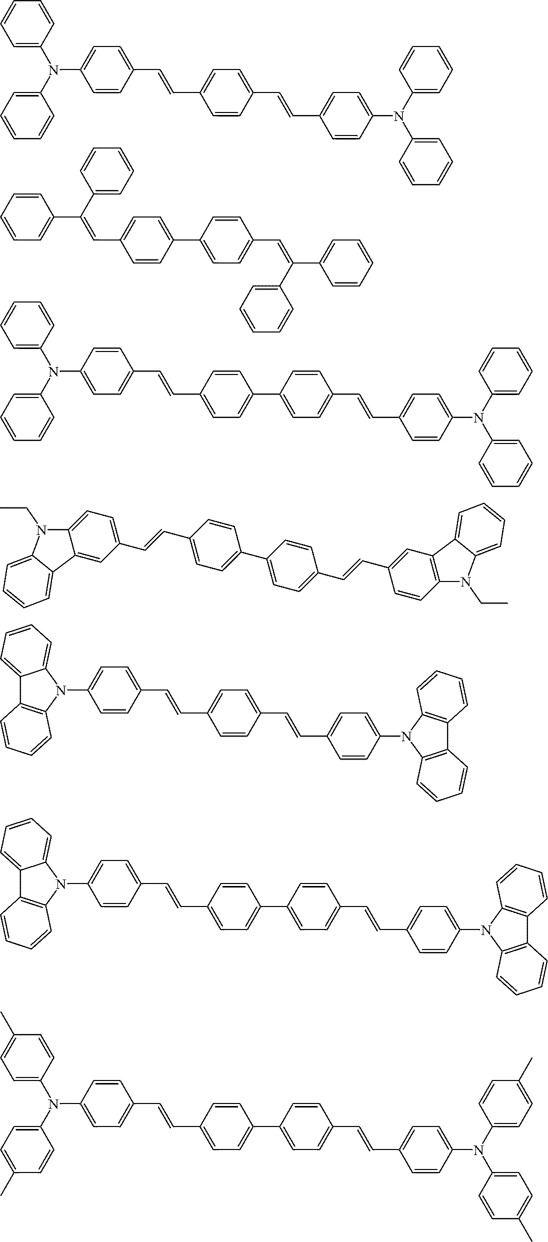

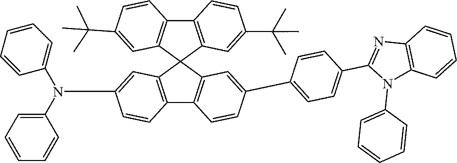 [SMILES: CC(C)(C)c1ccc2c(c1)C1(c3cc(-c4ccc(-c5nc6ccccc6n5-c5ccccc5)cc4)ccc3-c3ccc(N(c4ccccc4)c4ccccc4)cc31)c1cc(C(C)(C)C)ccc1-2]

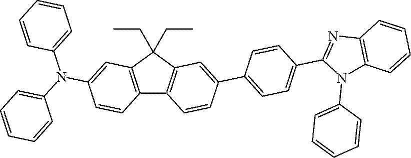 [SMILES: CCC1(CC)c2cc(-c3ccc(-c4nc5ccccc5n4-c4ccccc4)cc3)ccc2-c2ccc(N(c3ccccc3)c3ccccc3)cc21]

Examples of green emitters (receptor):

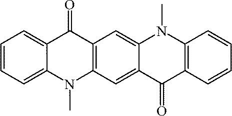 [SMILES: Cn1c2ccccc2c(=O)c2cc3c(cc21)c(=O)c1ccccc1n3C]

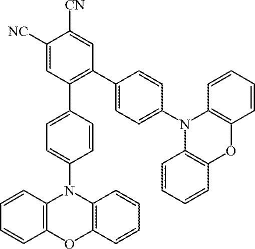 [SMILES: N#Cc1cc(-c2ccc(N3c4ccccc4Oc4ccccc43)cc2)c(-c2ccc(N3c4ccccc4Oc4ccccc43)cc2)cc1C#N]

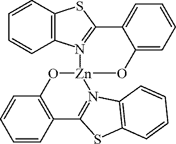

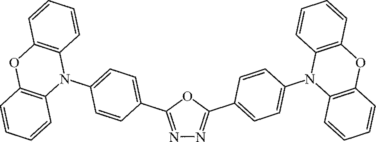 [SMILES: c1ccc2c(c1)Oc1ccccc1N2c1ccc(-c2nnc(-c3ccc(N4c5ccccc5Oc5ccccc54)cc3)o2)cc1]

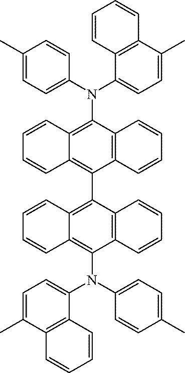

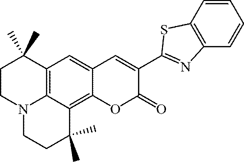

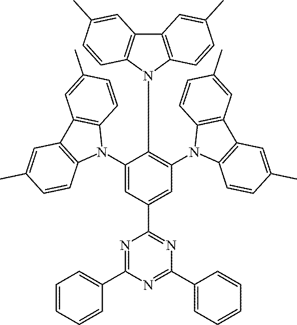

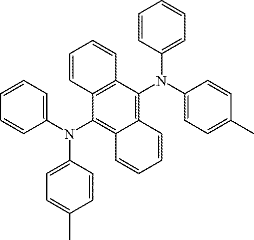 [SMILES: Cc1ccc(N(c2ccccc2)c2c3ccccc3c(N(c3ccccc3)c3ccc(C)cc3)c3ccccc23)cc1]

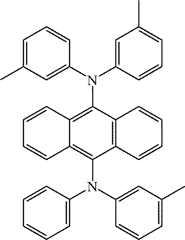

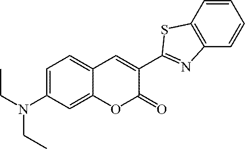 [SMILES: CCN(CC)c1ccc2cc(-c3nc4ccccc4s3)c(=O)oc2c1]

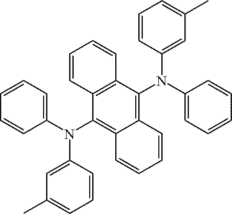 [SMILES: Cc1cccc(N(c2ccccc2)c2c3ccccc3c(N(c3ccccc3)c3cccc(C)c3)c3ccccc23)c1]

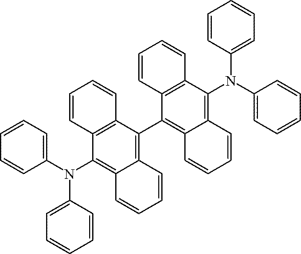 [SMILES: c1ccc(N(c2ccccc2)c2c3ccccc3c(-c3c4ccccc4c(N(c4ccccc4)c4ccccc4)c4ccccc34)c3ccccc23)cc1]

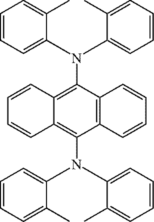 [SMILES: Cc1ccccc1N(c1ccccc1C)c1c2ccccc2c(N(c2ccccc2C)c2ccccc2C)c2ccccc12]

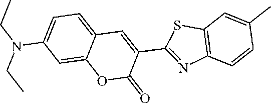 [SMILES: CCN(CC)c1ccc2cc(-c3nc4ccc(C)cc4s3)c(=O)oc2c1]

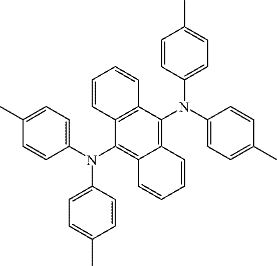

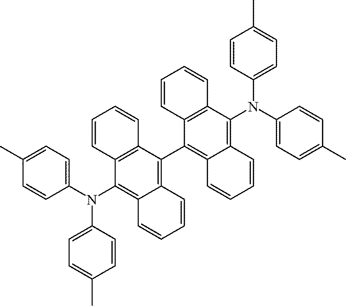

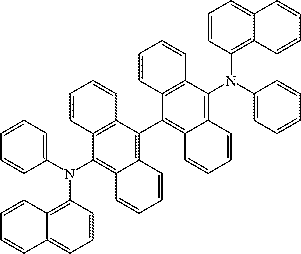 [SMILES: c1ccc(N(c2cccc3ccccc23)c2c3ccccc3c(-c3c4ccccc4c(N(c4ccccc4)c4cccc5ccccc45)c4ccccc34)c3ccccc23)cc1]

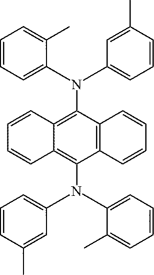 [SMILES: Cc1cccc(N(c2ccccc2C)c2c3ccccc3c(N(c3cccc(C)c3)c3ccccc3C)c3ccccc23)c1]

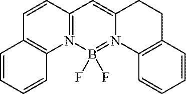

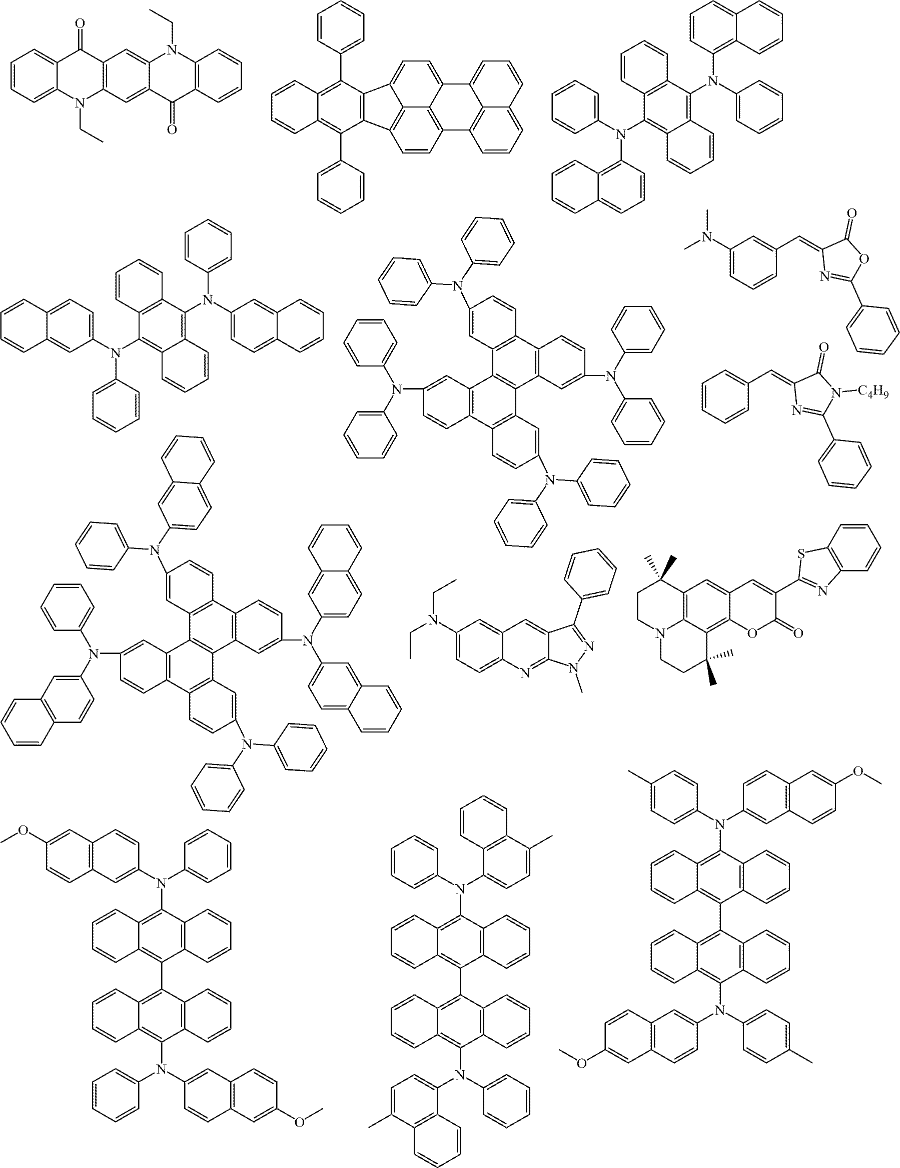

Examples of red emitters (receptor):

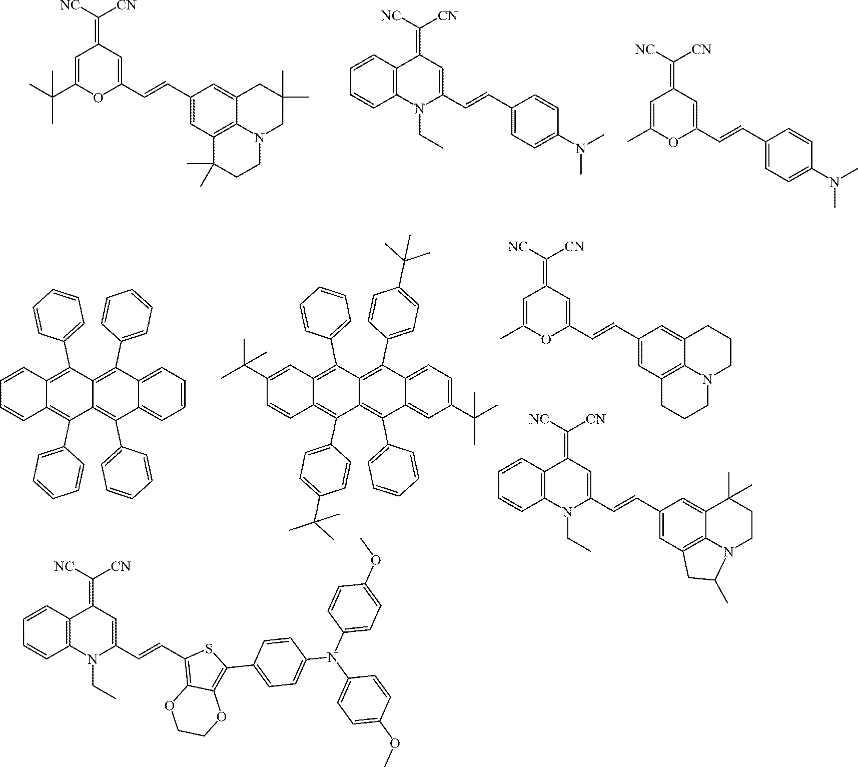

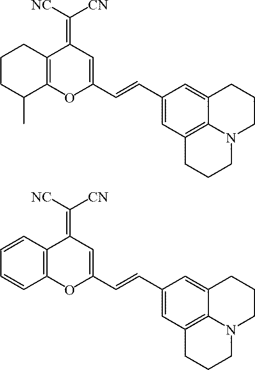 [SMILES: CC1CCCC2=C1OC(/C=C/c1cc3c4c(c1)CCCN4CCC3)=CC2=C(C#N)C#N ; N#CC(C#N)=C1C=C(/C=C/c2cc3c4c(c2)CCCN4CCC3)Oc2ccccc21]

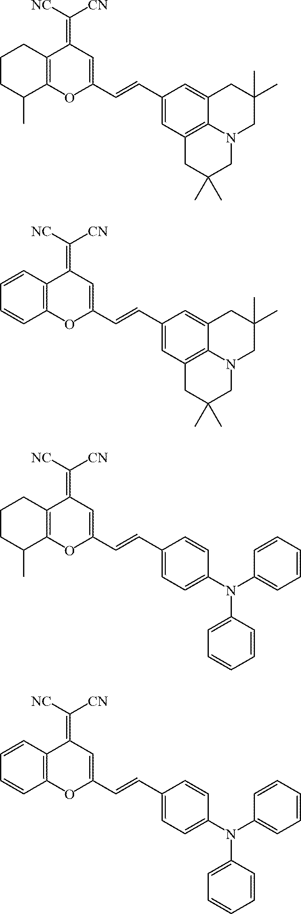 [SMILES: CC1CCCC2=C1OC(/C=C/c1cc3c4c(c1)CC(C)(C)CN4CC(C)(C)C3)=CC2=C(C#N)C#N ; CC1(C)Cc2cc(/C=C/C3=CC(=C(C#N)C#N)c4ccccc4O3)cc3c2N(C1)CC(C)(C)C3 ; CC1CCCC2=C1OC(/C=C/c1ccc(N(c3ccccc3)c3ccccc3)cc1)=CC2=C(C#N)C#N ; N#CC(C#N)=C1C=C(/C=C/c2ccc(N(c3ccccc3)c3ccccc3)cc2)Oc2ccccc21]

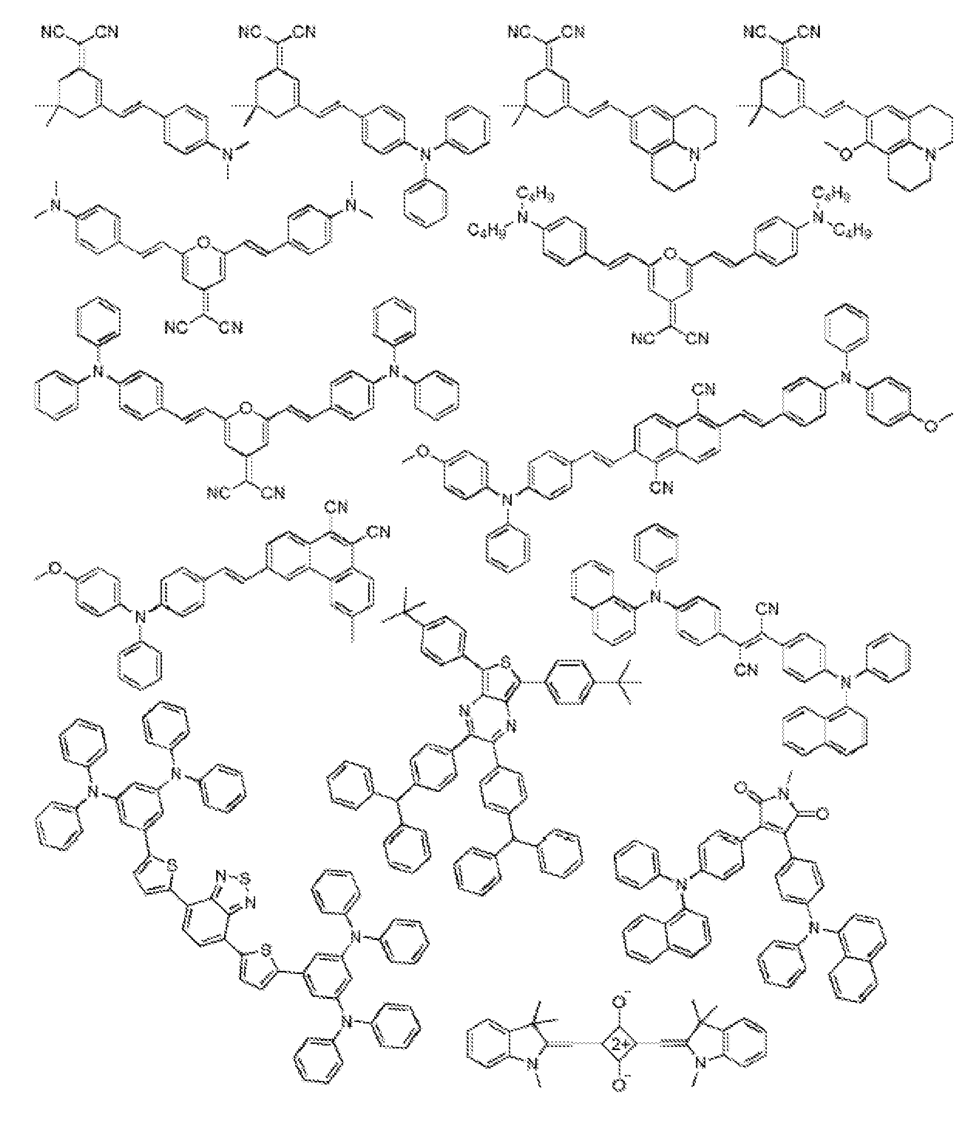 [SMILES: c1ccc(N(c2ccccc2)c2c3ccccc3c(N(c3ccccc3)c3ccccc3)c3ccccc23)cc1]

Examples of other proper fluorescent receptor molecules:

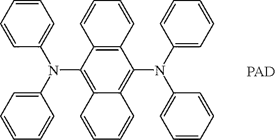 [SMILES: CC(C)(C)c1ccc(-c2c3ccc(C(C)(C)C)cc3c(-c3ccccc3)c3c(-c4ccc(C(C)(C)C)cc4)c4ccc(C(C)(C)C)cc4c(-c4ccccc4)c23)cc1]

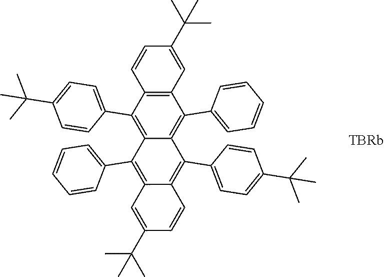 [SMILES: c1ccc(-c2c3c(c(-c4ccccc4)c4ccccc24)-c2ccc4c5ccc6c7c(ccc(c8ccc-3c2c84)c75)-c2c-6c(-c3ccccc3)c3ccccc3c2-c2ccccc2)cc1]

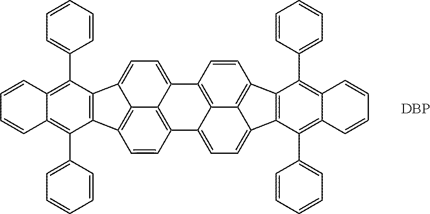 [SMILES: CC(C)(C)c1ccc(N(c2ccc(C(C)(C)C)cc2)c2c3ccccc3c(N(c3ccc(C(C)(C)C)cc3)c3ccc(C(C)(C)C)cc3)c3ccccc23)cc1]

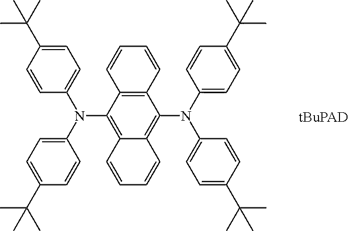 [SMILES: CC(C)(c1ccccc1)c1ccc(N(c2ccc(C(C)(C)c3ccccc3)cc2)c2c3ccccc3c(N(c3ccc(C(C)(C)c4ccccc4)cc3)c3ccc(C(C)(C)c4ccccc4)cc3)c3ccccc23)cc1]

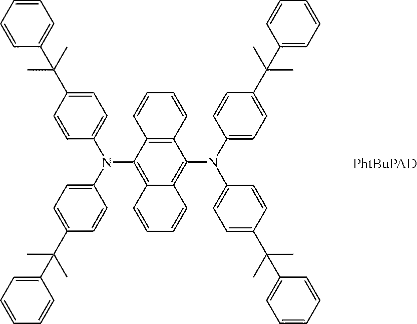 [SMILES: c1ccc(-c2c3c4cccc5c(N(c6ccccc6)c6ccccc6)ccc(c3c(-c3ccccc3)c3c6ccc(N(c7ccccc7)c7ccccc7)c7cccc(c23)c76)c54)cc1]

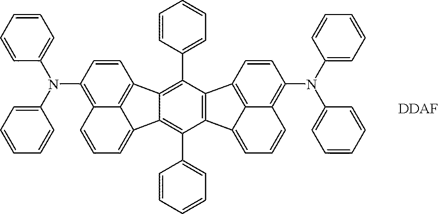 [SMILES: CC(C)(C)c1ccc(C(c2ccc(N(c3ccc(C(c4ccc(C(C)(C)C)cc4)(c4ccc(C(C)(C)C)cc4)c4ccc(C(C)(C)C)cc4)cc3)c3c4ccccc4c(N(c4ccc(C(c5ccc(C(C)(C)C)cc5)(c5ccc(C(C)(C)C)cc5)c5ccc(C(C)(C)C)cc5)cc4)c4ccc(C(c5ccc(C(C)(C)C)cc5)(c5ccc(C(C)(C)C)cc5)c5ccc(C(C)(C)C)cc5)cc4)c4ccccc34)cc2)(c2ccc(C(C)(C)C)cc2)c2ccc(C(C)(C)C)cc2)cc1]

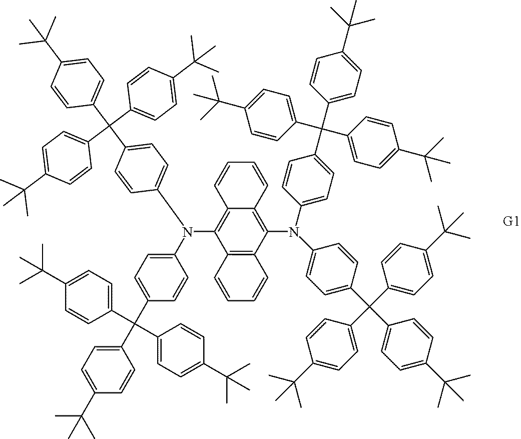

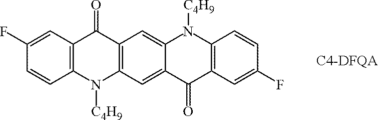

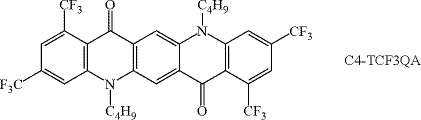

The synthesis of the mentioned Ce(III) donor chelate and the synthesis of the fluorescent receptor molecules are known in the art.

The superfluorescence-producing composition which has the Ce(III) donor component and fluorescent receptor component or consists of the Ce(III) donor component and fluorescent receptor component may be used for the following devices, preferably, used for an organic light emitting diode (OLED), light emitting electrochemical cell (LEEC), an OLED sensor (in particular to a vapor or gas sensor without seal shielding), an organic light emitting transistor and organic laser.

Particularly preferably, the composition which has the Ce(III) donor component and fluorescent receptor component or consists of the Ce(III) donor component and fluorescent receptor component is applied in OLED. The OLED device consists of multiple well-matched films. The corresponding examples have been disclosed for many times, which is thus known by a person skilled in the art.

Based on the present invention, doping needs to be performed in various components of the light emitting layer of OLED. The light emitting layer contains donor and receptor components, which may be achieved by vacuum sublimation or vapor deposition in a way of solution (for example, dip-coating and ink-jet printing). The light emitting layer has a host material; and the lowest triplet state is higher than the state ²D_{3/2} of the Ce(III) ion in energy or preferably higher than the states S₁(L) and T₁(L) of the Ce(III) chelate ligand. The corresponding host materials and T₁ (host) and S₁(host) energy have been known by a person skilled in the art. The doping amount of the Ce(III) component is 99%-10%, preferably 12%-18% (weight percentage). The doping amount of the receptor component is within 5%-0.5%, preferably 1%. Such a low concentration is necessary, and is to minimize the efficiency loss caused by direct electric charge capture or direct exciton formation on a receptor, and is also to avoid transferring the short-range dexter energy to the T₁ state of the receptor to a large extent. Based on these reasons, preferably, the donor and/or receptor component, for example, is substituted by space-expanded tert-butyl (for example, for the donor: formula I having carbazolyl R¹ substituted by tert-butyl and for example, for the receptor: formula VII).

The advantages of the composition of the present invention are superior to those of the prior art, especially in the aspect of reducing the emission decay time of the produced superfluorescence by one to three orders of magnitude. Compared with the prior art, the present invention greatly prolongs the service life of the device, in particular to dark blue emission. Moreover, compared with the prior art, the present invention can further significantly decrease the roll-off properties of the device by shortening the emission decay time.

### BRIEF DESCRIPTION OF DRAWINGS

FIG. 1 shows a photophysical process of, for example, dark blue superfluorescence emission achieved by a dual capture mechanism.

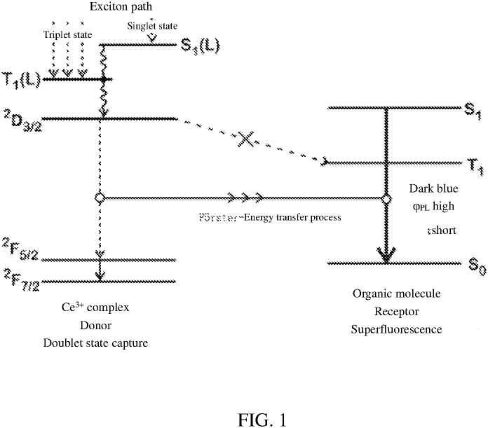

The singlet and triplet excitons produced in an OLED light emitting layer are captured by the states S₁(L) and T₁(L) of a Ce(III) chelate ligand. Rapid intramolecular energy transfer causes that the lowest excited state is occupied by the state ²D_{3/2} in the Ce(III) chelate. The decay time of the fluorescent radiative jump (no receptor) to the states ²F_{5/2} and ²F_{7/2} is 50-100 ns. Such kind of Ce(III) chelate is used as a donor to transfer energy to for example, the state S₁ of an organic receptor molecule of dark blue fluorescence through a Förster-energy transfer mechanism (FRET) of rapid fluorescence resonance, thus producing fluorescence emission finally. The selected organic receptor molecule has a narrow FWHM (for example, <0.2 eV) and higher photoluminescent quantum efficiency φ_{PL} (for example, 90%) and very short emission decay time (for example, 2 ns). The short range non-radiative energy transfer from the state ²D_{3/2} to the state T₁ of a receptor based on a Dexter mechanism may be greatly inhibited. The method may be also used to produce green or red superfluorescence.

### DETAILED DESCRIPTION OF EMBODIMENTS

The present invention will be further described in detail with reference to the examples.

### Example 1

Structure of the OLED light emitting layer: layer thickness: 20 nm; host: 2,8-bis(diphenylphosphineoxy)dibenzofuran (DBFPO) doped with 15% Ce[B(pz)₄]₃, pz=pyrazolyl and 1% BPPyA (formula VIII).

### Example 2

Structure of the OLED light emitting layer: layer thickness: 20 nm; host: 2,8-bis(diphenylphosphineoxy) dibenzofuran (DBFPO) doped with 15% Ce[B(pz)_{4]3}, pz=pyrazolyl and 1% compound of formula IX.

### Example 3

Structure of the OLED light emitting layer: layer thickness: 20 nm; host: 2,8-bis(diphenylphosphineoxy) dibenzofuran (DBFPO) doped with 15% Ce[B(pz)₃(Cz-tert-Butyl)₃], pz=pyrazolyl and Cz-tert-Butyl=carbazolyl substituted by tert-butyl; and 1% compound of formula VIII.

### Example 4

Structure of the OLED light emitting layer: layer thickness: 20 nm; host: 2,8-bis(diphenylphosphineoxy) dibenzofuran (DBFPO) doped with 18% compound of formula VI and 1% compound of formula VII.

1. A molecule, having the following structural formula I or II, or consisting of the following structural formula I or II: 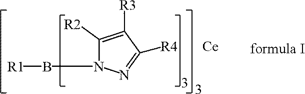 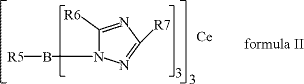
wherein:
R¹ is selected from pyrazolyl, triazolyl, heteroaryl, alkyl, aryl, alkoxy, phenol group, amido and acylamino; these groups are substituted or unsubstituted; R⁵ is R¹ or H; and
R², R³, R⁴, R⁶, R⁷ are independently selected from H, halogen, hydrocarbonyl or hydrocarbonyl containing a heteroatom, especially alkyl, aryl and heteroaryl; preferably, R ²—R ⁷ are each independently fluorated, namely, particularly having at least one F.

2. The molecule according to claim 1, having the following structure, or consisting of the following structure: 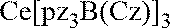
wherein Cz is carbazolyl and pz is pyrazolyl,
wherein optionally, Cz is each independently substituted by one or two tert-butyl in any position.

3. The molecule according to claim 2, having or consisting of the following structure: 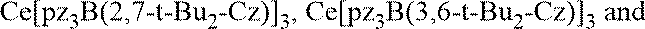 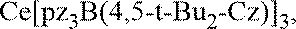
wherein t-Bu is tert-butyl.

4. The molecule according to claim 1, having the following structural formula III or IV, or consisting of the following structural formula III or IV: 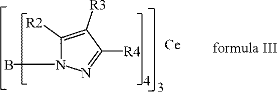 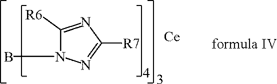
being a tetra(cis)pyrazolyl borate ligand or a tetra(cis)triazolyl borate ligand herein.

5. The molecule according to claim 4, wherein R², R³, R⁴, R⁶ and R⁷ are each independently selected from hydrogen and halogen, or one optional hydrocarbonyl containing a heteroatom and/or substituted or unsubstituted hydrocarbonyl, wherein the heteroatom is particularly selected from O, S, N, P, Si, Se, F, Cl, Br and/or I.

6. The molecule according to claim 5, wherein R², R³, R⁴, R⁶ and R⁷ are hydrogen and halogen.

7. A molecule, having the following structural formula V or VI, or consisting of the following structural formula V or VI: 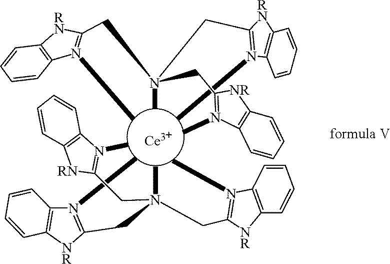 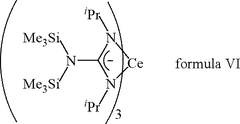
wherein R is CH₃CH₂, CH₃CH₂CH₂ or CH₃-CH-CH₃.

8. The molecule according to any one of claims 1-7, optionally, having at least one deuterium.

9. An application of the molecule according to any one of claims 1-7 as a neutral donor molecule in a composition consisting of a fluorescent receptor molecule therewith.

10. A composition, consisting of:
a neutral donor molecule with the molecule according to any one of claims 1-8 as a Ce(III) chelate form, and
a fluorescent receptor molecule, particularly being the compound according to formulas VII-IX,

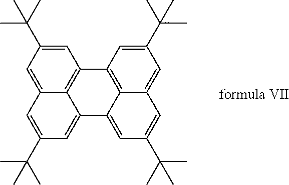 [SMILES: Cc1ccc(C)c(N(c2ccc3ccc4c(N(c5cc(C)ccc5C)c5cccc6c5oc5ccccc56)ccc5ccc2c3c54)c2cccc3c2oc2ccccc23)c1]

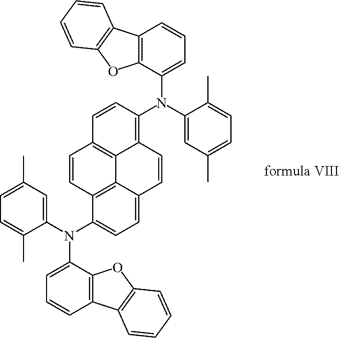 [SMILES: c1ccc(N2c3ccccc3B3c4ccccc4N(c4ccccc4)c4cccc2c43)cc1]

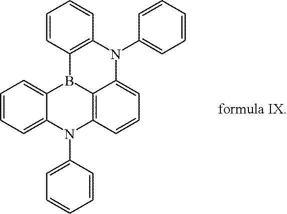

11. The composition according to claim 10, wherein the neutral donor molecule has a Ce(III) central ion, which is eight to twelve-coordinated, and particularly coordinated with an organic ligand.

12. The composition according to claim 11, wherein the organic ligand is a two-coordinated or preferably, three-coordinated chelating ligand and/or the lowest triplet energy of the organic ligand is higher than an excited state energy of the Ce(III) chelate with the lowest energy.

13. The composition according to claims 10-12, wherein the organic ligand has one or two aromatic or heteromatic ring systems, used for capturing singlet excitons and triplet excitons such that the lowest ligand excited singlet state S₁(L) and the lowest ligand excited triplet state T₁(L) are occupied, and perform rapid intersystem crossing from S₁(L) to T₁(L), and rapidly transfer to the center of the Ce(III) therewith via intramolecular energy.

14. The composition according to claim 13, wherein the fluorescent receptor molecule has: wherein
the receptor has a decimal molar extinction coefficient greater than 20,000 Lmol⁻¹cm⁻¹;
a full width at half maximum (FWHM) less than 0.25 eV, particularly less than 0.2 eV;
an emission quantum efficiency φ_{PL} greater than 70%, particularly greater than 90%;
emission decay time τ less than 10 ns, particularly less than 2 ns; and/or
a maximum emission peak within a range of 420 nm-480 nm, in particular to a dark blue spectrum region.

15. An application of the composition according to claims 10-14 for the preparation of a photoelectric device, particularly selected from an organic light emitting diode (OLED), light emitting electrochemical cell (LEEC), an OLED sensor and an organic light emitting transistor and organic laser.

16. A photoelectric device, having the molecule according to claims 1-9 or the composition of claims 10-14.

17. The photoelectric device according to claim 16, comprising
a substrate;
an anode and
a cathode, wherein the anode or the cathode is applied on the substrate; and
at least one light emitting layer which is disposed between the anode and the cathode, and has the molecule of claims 1-9 or the composition of claims 10-14.

18. The photoelectric device according to claim 17, wherein a doping mass ratio of the Ce(III) chelate donor molecule in the light emitting layer accounts for 99%-10% in the light emitting layer, in particular being 18%-12%.

19. The photoelectric device according to claim 18, wherein a doping mass ratio of the fluorescent receptor molecule accounts for 0.5%-5% in the emitting layer, in particular being 1%.

20. A method for preparing the photoelectric device according to claims 16-19, wherein the molecule according to claims 1-9 or the composition of claims 10-14 is used.

21. A method for completely capturing all singlet and triplet excitons in a photoelectric device, wherein the molecule of claims 1-9, as a Ce(III) chelate donor, is used for non-radiative energy transfer to a fluorescent receptor.

22. The method according to claim 21, wherein a fluorescent receptor molecule emitting a green or red light is used to produce a superfluorescence which has a short service life, in particular being less than 10 ns or greater than 2 ns and has a high color purity to the corresponding spectral regions.
